(19) United States
(12) Patent Application Publication
(10) Pub. No.: US 2026/0198056 A1
(43) Pub. Date: Jul. 9, 2026

(54) SEMICONDUCTOR DEVICE

(71) Applicant: FUJI ELECTRIC CO., LTD., Kawasaki-shi (JP)

(72) Inventor: Takahide TANAKA, Matsumoto-city (JP)

(73) Assignee: FUJI ELECTRIC CO., LTD., Kawasaki-shi (JP)

(21) Appl. No.: 19/398,926

(22) Filed: Nov. 24, 2025

(30) Foreign Application Priority Data
Jan. 8, 2025 (JP) 2025-002822

(51) Int. Cl. H10D 64/00; H03K 19/003; H10D 1/47; H10D 30/65; H10D 84/80

(52) U.S. Cl. CPC H10D 64/115; H03K 19/00361; H10D 1/47; H10D 30/655; H10D 64/112; H10D 84/817; H10D 30/657

(57) ABSTRACT

A semiconductor device includes: a base body of a first conductivity-type; a first well region of a second conductivity-type provided on a top surface side of the base body and provided with a high-side circuit; a voltage blocking structure provided to surround a circumference of the first well region; a level shifter provided in the voltage blocking structure; and first and second resistive field plates provided over the voltage blocking structure with an insulating film interposed, each having one end electrically connected to different semiconductor regions electrically connected to the high-side circuit.

### CROSS-REFERENCE TO RELATED APPLICATION

This application claims benefit of priority under 35 USC 119 based on Japanese Patent Application No. 2025-002822 filed on January 8, 2025, the entire contents of which are incorporated by reference herein.

### BACKGROUND OF THE INVENTION

### 1. Field of the Invention

The present disclosure relates to semiconductor devices.

### 2. Description of the Related Art

JP5748353B2 discloses a semiconductor device including a resistive field plate (RFP) implemented by a plurality of resistive elements formed into a meandering state. JP6885013B2 discloses a semiconductor device including a spiral resistor partly implemented by a metal layer and further including a meandering resistor under the metal layer so as to provide two independent RFPs.

JP6597269B2 discloses a semiconductor device including two or more sense resistors each also serving as an RFP so as to detect a plurality of high-side potentials.

The conventional semiconductor devices with the configurations as described above cannot sufficiently exhibit the advantages of the respective RFPs connected to different targets synchronously.

### SUMMARY OF THE INVENTION

The present disclosure provides a semiconductor device having a configuration capable of synchronously exhibiting advantages of a plurality of RFPs connected to different targets.

An aspect of the present disclosure inheres in a semiconductor device including: a base body of a first conductivity-type; a first well region of a second conductivity-type provided on a top surface side of the base body and provided with a high-side circuit; a voltage blocking structure provided to surround a circumference of the first well region; a level shifter provided in the voltage blocking structure; and first and second RFPs provided over the voltage blocking structure with an insulating film interposed, each having one end electrically connected to different semiconductor regions electrically connected to the high-side circuit.

### BRIEF DESCRIPTION OF THE DRAWINGS

FIG. 1 is a circuit diagram illustrating a semiconductor device according to a first embodiment;

FIG. 2 is a plan view illustrating the semiconductor device according to the first embodiment;

FIG. 3 is a cross-sectional view taken along line A-A’ in FIG. 2;

FIG. 4 is a partly-enlarged plan view illustrating the semiconductor device according to the first embodiment;

FIG. 5 is a cross-sectional view taken along line B-B’ in FIG. 4;

FIG. 6 is a cross-sectional view taken along line C-C’ in FIG. 4;

FIG. 7 is a plan view illustrating a semiconductor device according to a second embodiment;

FIG. 8 is a partly-enlarged plan view illustrating the semiconductor device according to the second embodiment;

FIG. 9 is a cross-sectional view taken along line A-A’ in FIG. 8;

FIG. 10 is a cross-sectional view taken along line B-B’ in FIG. 8;

FIG. 11 is a plan view illustrating a semiconductor device according to a third embodiment;

FIG. 12 is a plan view illustrating a semiconductor device according to a fourth embodiment;

FIG. 13 is a plan view illustrating a semiconductor device according to a fifth embodiment;

FIG. 14 is a plan view illustrating a semiconductor device according to a sixth embodiment;

FIG. 15 is a plan view illustrating a semiconductor device according to a seventh embodiment;

FIG. 16 is a plan view illustrating a semiconductor device according to an eighth embodiment;

FIG. 17 is a cross-sectional view illustrating a semiconductor device according to a ninth embodiment;

FIG. 18 is a cross-sectional view illustrating a semiconductor device according to a tenth embodiment;

FIG. 19 is a plan view illustrating a resistive field plate according to another embodiment;

FIG. 20 is a plan view illustrating a resistive field plate according to still another embodiment; and

FIG. 21 is a plan view illustrating a resistive field plate according to still another embodiment.

### DETAILED DESCRIPTION

With reference to the drawings, first to tenth embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to tenth embodiments described below merely illustrate schematically devices and methods for specifying and giving shapes to the technical idea of the present disclosure, and the span of the technical idea is not limited to materials, shapes, structures, and relative positions of elements described herein.

In the specification, a "carrier supply region" means a semiconductor region which supplies majority carriers as a main current. The carrier supply region is assigned to a semiconductor region which will be a source region in a field-effect transistor (FET) or a static induction transistor (SIT), an emitter region in an insulated-gate bipolar transistor (IGBT), and an anode region in a diode, a static induction (SI) thyristor or a gate turn-off (GTO) thyristor. A "carrier reception region" means a semiconductor region which receive the majority carriers as the main current. The carrier reception region is assigned to a semiconductor region which will be the drain region in the FET or the SIT, the collector region in the IGBT, and the cathode region in the diode, SI thyristor or GTO thyristor.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is a p-type and a second conductivity-type is an n-type. Further, a semiconductor region denoted by the symbol "n" or "p" attached with "+" indicates that such semiconductor region has a relatively high impurity concentration as compared to a semiconductor region denoted by the symbol "n" or "p" without "+". A semiconductor region denoted by the symbol "n" or "p" attached with "-" indicates that such semiconductor region has a relatively low impurity concentration as compared to a semiconductor region denoted by the symbol "n" or "p" without "-". However, even when the semiconductor regions are denoted by the same reference symbols "n" and "n", it is not indicated that the semiconductor regions have exactly the same impurity concentration. Moreover, the members and the regions that are limited by adding "first conductivity-type" and "second conductivity-type" in the following description indicate the members and the regions formed of semiconductor materials without particular obvious limitations.

### FIRST EMBODIMENT

### Circuit of Semiconductor Device

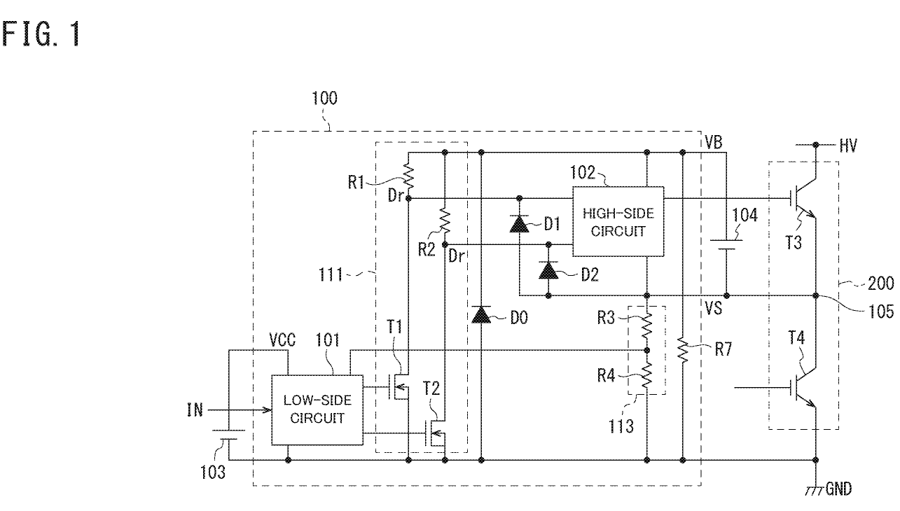

A semiconductor device according to a first embodiment is illustrated below with a high-voltage integrated circuit (HVIC) 100, as illustrated in FIG. 1. The HVIC 100 drives a power conversion part 200, which is a target to be driven, for one phase in a bridge circuit for power conversion, for example. The power conversion part 200 includes a high-potential side switching element T3 and a low-potential side switching element T4 that are connected in series so as to implement a half-bridge circuit. FIG. 1 illustrates a case in which the high-potential side switching element T3 and the low-potential side switching element T4 are each an IGBT, but the respective switching elements may be any other power switching element such as a metal-oxide-semiconductor field-effect transistor (MOSFET).

An HV potential on a high-potential side is connected to a collector of the high-potential side switching element T3. A ground potential (a GND potential) on a low-potential side is connected to an emitter of the low-potential side switching element T4. A VS potential on a negative-electrode side of a power supply (a high-potential side power supply) 104 on the high-potential side is connected to a connection point 105 between an emitter of the high-potential side switching element T3 and a collector of the low-potential side switching element T4. The VS potential is an intermediate potential of the half-bridge circuit implemented by the high-potential side switching element T3 and the low-potential side switching element T4. A load such as a motor (not illustrated) can be connected to the connection point 105.

The HVIC 100 applies a drive signal, to a gate of the high-potential side switching element T3, for turning ON/OFF to drive the gate of the high-potential side switching element T3 in accordance with an input signal IN from an external microcomputer, for example. The HVIC 100 includes a low-potential side circuit (a low-side circuit) 101, a high-potential side circuit (a high-side circuit) 102, a level-shift circuit 111, a voltage-division resistor 113, and a resistor R7. A VCC potential on a positive-electrode side of a power supply (a low-potential side power supply) 103 on the low-potential side and a GND potential on a negative-electrode side of the low-potential side power supply 103 are connected to the low-side circuit 101. Gates of level-shift elements (level shifters) T1 and T2 of the level-shift circuit 111 are also connected to the low-side circuit 101.

The low-side circuit 101 operates with the GND potential used as a reference potential and operates with the VCC potential higher by about 15 volts than the GND potential used as a power-supply potential. The low-side circuit 101 generates a GND-potential-based ON/OFF signal in accordance with the input signal IN based on the GND potential from the external microcomputer or the like, and outputs the generated signal to the respective gates of the level shifters T1 and T2.

The level-shift circuit 111 includes the level shifters T1 and T2 and level-shift resistors R1 and R2. The respective level shifters T1 and T2 execute signal transmission between the low-side circuit 101 and the high-side circuit 102. The respective level shifters T1 and T2 convert the ON/OFF signal based on the GND potential output from the low-side circuit 101 into an ON/OFF signal based on the VS potential, and outputs the converted ON/OFF signal to the high-side circuit 102. The respective level shifters T1 and T2 are implemented by a high-voltage n-channel MOSFET (HVNMOS), for example.

The GND potential is connected to a source of the level shifter T1. The high-side circuit 102 and one end of the level-shift resistor R1 are connected to a drain of the level shifter T1. A VB potential on the positive-electrode side of the high-potential side power supply 104 is connected to the other end of the level-shift resistor R1. A cathode of a diode D1 is connected to the drain of the level shifter T1 and the one end of the level-shift resistor R1 . The high-side circuit 102 and the VS potential on the negative-electrode side of the high-potential side power supply 104 are connected to an anode of the diode D1. The diode D1 has a function capable of avoiding an excessive reduction in drain potential (Dr potential) of the level shifter T1.

The GND potential is connected to a source of the level shifter T2. The high-side circuit 102 and one end of the level-shift resistor R2 are connected to a drain of the level shifter T2. The VB potential on the positive-electrode side of the high-potential side power supply 104 is connected to the other end of the level-shift resistor R2. A cathode of a diode D2 is connected to the drain of the level shifter T2 and the one end of the level-shift resistor R2. The high-side circuit 102 and the VS potential on the negative-electrode side of the high-potential side power supply 104 are connected to an anode of the diode D2. The diode D2 has a function capable of avoiding an excessive reduction in drain potential (Dr potential) of the level shifter T2.

A cathode of a high-voltage diode D0, which is referred to as a high-voltage junction termination (HVJT), is connected to the VB potential on the positive-electrode side of the high-potential side power supply 104. The GND potential is connected to an anode of the diode D0.

The high-side circuit 102 operates with the VS potential, which is an intermediate potential of the half-bridge circuit, used as a reference potential, and operates with the VB potential higher than the VS potential used as a power-supply potential. The high-side circuit 102 outputs a drive signal based on the VS potential to the gate of the high-potential side switching element T3 in accordance with the ON/OFF signal from the respective level shifters T1 and T2 so as to drive the gate of the high-potential side switching element T3. The high-side circuit 102 includes, at the output stage, a CMOS circuit of an n-channel MOSFET and a p-channel MOSFET , for example.

The voltage-division resistor 113 includes a resistor R3 and a resistor R4. One end of the resistor R3 is connected to the high-side circuit 102 and the VS potential. One end of the resistor R4 is connected to the other end of the resistor R3. The GND potential is connected to the other end of the resistor R4. A connection point between the resistor R3 and the resistor R4 is connected to the low-side circuit 101. One end of the resistor R7 is connected to the VB potential, and the other end is connected to the GND potential.

The VB potential is a maximum potential to be applied to the HVIC 100, and is kept higher than the VS potential by about 15 volts in a normal operation not influenced by noise. The VS potential repeats a rise and a drop between the HV potential on the high-potential side (in a range of about 100 volts or higher and 400 volts or lower, for example) and the GND potential on the low-potential side when the high-potential side switching element T3 and the low-potential side switching element T4 are complementarily turned ON and OFF, and fluctuates between zero to several hundreds of volts. The VS potential can fall below zero.

### Configuration of Semiconductor Device

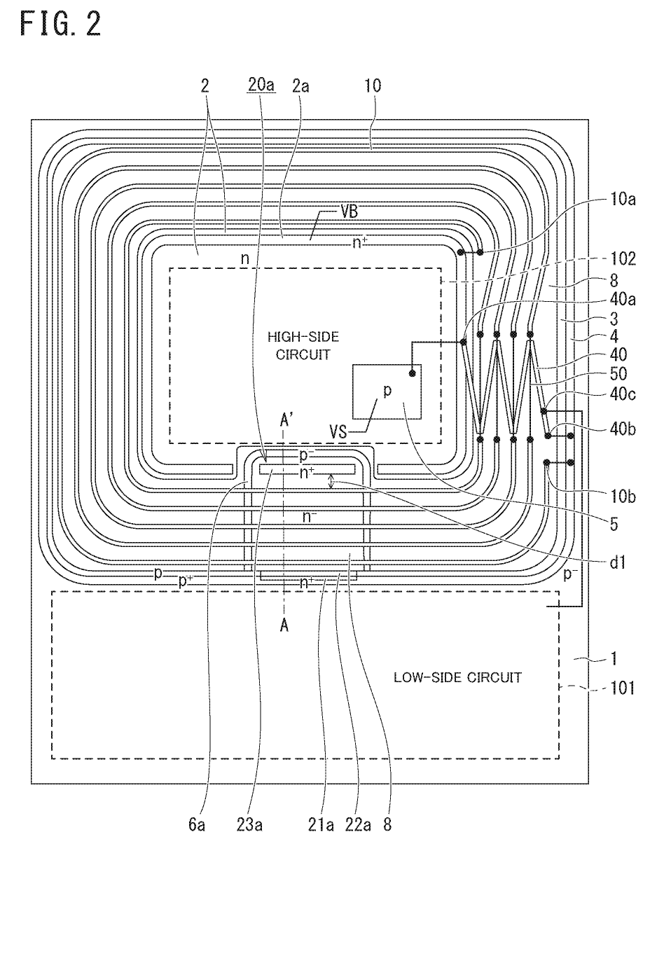

FIG. 2 is a planar layout of the semiconductor device according to the first embodiment corresponding to the HVIC 100 illustrated in FIG. 1. The semiconductor device according to the first embodiment includes a base body (a semiconductor chip) 1 of a first conductivity-type (p⁻-type). The base body 1 is a silicon (Si) substrate, for example. The base body 1 may be a semiconductor substrate including material such as silicon carbide (SiC), a gallium nitride (GaN), a gallium oxide (Ga₂O₃), gallium arsenide (GaAs), and diamond (C). The base body 1 may be implemented by a semiconductor substrate of p⁻-type and an epitaxial growth layer of p⁻-type epitaxially grown on the semiconductor substrate.

The base body 1 may be fixed at the GND potential. A well region 2, which is a semiconductor region of a second conductivity-type (n-type), is provided on the top surface side (at the upper part) of the base body 1. The well region 2 has a substantially rectangular planar pattern. The well region 2 is provided with the high-side circuit (high-side circuit region) 102. FIG. 2 omits the illustration of the respective elements included in the high-side circuit 102.

A contact region (a pickup region) 2a, which is a semiconductor region of n⁺-type, is provided on the top surface side (at the upper part) of the well region 2. The VB potential is applied to the contact region 2a. A well region 5 of p-type is provided on the top surface side (at the upper part) of the well region 2. The VS potential is applied to the well region 5.

A voltage blocking region 8, which is a semiconductor region of n⁻-type, having a lower impurity concentration than the well region 2 is provided to surround the circumference of the well region 2 so as to be in contact with each other. The voltage blocking region 8 is formed into a loop-like shape, and the outline has a substantially rectangular planar pattern.

A voltage blocking region 3, which is a semiconductor region of p-type, is provided to surround the circumference of the voltage blocking region 8 so as to be in contact with each other. The voltage blocking region 3 is formed into a loop-like shape, and the outline has a substantially rectangular planar pattern. The GND potential is applied to the voltage blocking region 3. The outer circumference of the voltage blocking region 3 is surrounded by the base body 1.

A p-n junction between the p-type voltage blocking region 3 and the n⁻-type voltage blocking region 8 implements a voltage blocking structure (3, 8), which is referred to as a high-voltage junction termination (HVJT). The voltage blocking structure (3, 8) corresponds to the high-voltage diode D0 illustrated in FIG. 1. The voltage blocking structure (3, 8) is formed into a loop-like shape, and the outline has a substantially rectangular planar pattern. The voltage blocking structure (3, 8) electrically isolates the high-side circuit 102 provided on the inner circumferential side of the voltage blocking structure (3, 8) from the low-side circuit (low-side circuit region) 101 provided in the base body 1 on the outer circumferential side of the voltage blocking structure (3, 8). The provision of the voltage blocking structure (3, 8) enables a normal operation of the semiconductor device regardless of whether the potential of the high-side circuit 102 is led to be higher than the potential of the low-side circuit 101 by several hundreds of volts.

In the plan view of FIG. 2, the low-side circuit 101 is illustrated on the lower side of the high-side circuit 102 via the voltage blocking structure (3, 8). FIG. 2 omits the illustration of the respective elements included in the low-side circuit 101.

As illustrated in FIG. 2, the voltage blocking structure (3, 8) is provided with a level-shift element (a level shifter) 20a. The level shifter 20a is provided to include a part of the voltage blocking region 8. The level shifter 20a corresponds to the level shifter T1 illustrated in FIG. 1. FIG. 2 omits the illustration of a level shifter corresponding to the level shifter T2 illustrated in FIG. 2.

The level shifter 20a is implemented by a high-voltage n-channel MOSFET (HVNMOS). The level shifter 20a includes a carrier supply region (a source region) 21a of n⁺-type, a gate electrode 22a, and a carrier reception region (a drain region) 23a of n⁺-type . The source region 21a, the gate electrode 22a, and the drain region 23a each have a straight planar pattern to extend parallel to each other. A part of the voltage blocking region 8 interposed between the source region 21a and the drain region 23a serves as a drift region of the level shifter 20a.

An isolation region (a slit region) 6a, which is a semiconductor region of p⁻-type, is provided to surround the circumference of the level shifter 20a. The slit region 6a has a substantially U-shaped planar pattern having a bottom toward the high-side circuit 102 and having an opening toward the low-side circuit 101. The respective end parts of a pair of (two) opposed straight parts connected to the bottom of the substantially U-shaped slit region 6a are in contact with the voltage blocking region 3. The semiconductor device according to the first embodiment thus has a structure in which the level shifter 20a is arranged to be surrounded by the slit region 6a so as to be electrically isolated from the voltage blocking structure (3, 8), which is referred to as a divided RESURF structure.

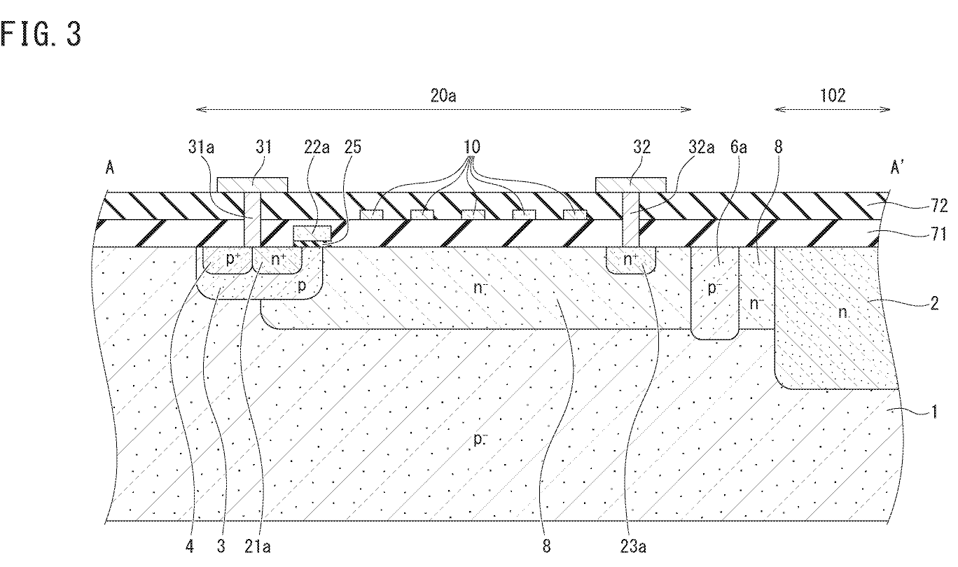

FIG. 3 is a cross-sectional view taken along line A-A’ across the level shifter 20a in FIG. 2. As illustrated in FIG. 3, the n-type well region 2 is provided at the upper part of the p⁻-type base body 1. The well region 2 is implemented by a diffusion layer to which n-type impurity ions are implanted. The well region 2 is provided with the high-side circuit 102.

The n⁻-type voltage blocking region 8 is provided in contact with the well region 2 at the upper part of the base body 1. The voltage blocking region 8 is implemented by a diffusion layer to which n-type impurity ions are implanted. The voltage blocking region 8 has a shallower depth than the well region 2. The p⁻-type slit region 6a is provided at the upper part of the base body 1 so as to penetrate the voltage blocking region 8 in the depth direction to reach the base body 1. The slit region 6a is implemented by a diffusion layer to which p-type impurity ions are implanted. The slit region 6a has a greater depth than the voltage blocking region 8.

As illustrated in FIG. 3, the level shifter 20a is separated from the n-type well region 2 by the p⁻-type slit region 6a. A part of the voltage blocking region 8 separated from the n-type well region 2 by the p⁻-type slit region 6a serves as the drift region of the level shifter 20a. The upper part of the voltage blocking region 8 serving as the drift region of the level shifter 20a is provided with a drain region 23a of n⁺-type. The drain region 23a is a diffusion layer to which n-type impurity ions are implanted.

An insulating film 71 and an insulating film 72 are provided on the top surface side of the drain region 23a. FIG. 2 omits the illustration of the insulating film 71 and the insulating film 72. A drain electrode 32 is connected to the drain region 23a through a via 32a made of metal, for example, provided in an opening (a contact hole) formed in the insulating film 71 and the insulating film 72. The drain electrode 32 may be made of metal mainly including aluminum (Al) or copper (Cu), for example.

The insulating film 71 may be a silicon oxide film (a SiO₂ film) or a silicon nitride film (a Si₃N₄ film), or may be a composite film including these films. The insulating film 71 may also be an insulating film obtained by chemical vapor deposition (CVD) by use of gas containing an organic silicon-based compound such as tetraethoxysilane (TEOS).

The insulating film 72 as used herein can be a silicon oxide film (a SiO₂ film) without containing impurities, which is generally referred to as a non-doped silicate glass (NSG) film, a phosphosilicate glass film (a PSG film), or a borosilicate glass film (a BSG film). The insulating film 72 can also be a single-layer film of a borophosphosilicate glass film (a BPSG film) or a silicon nitride film (a Si₃N₄ film), or a composite film including some of the above films combined together.

The p-type voltage blocking region 3 is provided at the upper part of the base body 1 so as to be in contact with the voltage blocking region 8 on the opposite side of the well region 2. The voltage blocking region 3 is implemented by a diffusion layer to which p-type impurity ions are implanted. A part of the voltage blocking region 3 in contact with the voltage blocking region 8 implementing the drift region of the level shifter 20a serves as a base region of the level shifter 20a.

The n⁺-type source region 21a is provided at the upper part of the voltage blocking region 3 serving as the base region of the level shifter 20a. The source region 21a is implemented by a diffusion layer to which n-type impurity ions are implanted. A contact region 4 of p⁺-type having a higher impurity concentration than the voltage blocking region 3 is provided in contact with the source region 21a at the upper part of the voltage blocking region 3 serving as the base region of the level shifter 20a. The contact region 4 is implemented by a diffusion layer to which p-type impurity ions are implanted.

A source electrode 31 is connected to the source region 21a and the contact region 4 through a via 31a made of metal, for example, provided in an opening (a contact hole) formed in the insulating film 71 and the insulating film 72. The source electrode 31 may be made of metal mainly including aluminum (Al) or copper (Cu), for example.

A gate electrode 22a is provided, through a gate insulating film 25, on the top surface side of the voltage blocking region 3 interposed between the source region 21a and the voltage blocking region 8. The gate insulating film 25 as used herein can be a single-layer film of a silicon dioxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 22a may be implemented by a polysilicon layer (a doped polysilicon layer) heavily doped with p-type impurities or n-type impurities, or may be made of refractory metal, such as titanium (Ti), tungsten (W), and nickel (Ni).

Semiconductor devices such as a HVIC are conventionally provided with a field plate over a HVJT and a HVNMOS in order to stably ensure breakdown voltage. Providing a resistive field plate (RFP) formed into a spiral or meandering state is particularly effective because of stronger suppressing force for potentials than a capacitive-coupling multiple floating field plate (MFFP) formed into a concentric state, so as to ensure high breakdown voltage. Typically, one end of an RFP is connected to a potential such as a VB potential and a VS potential in a high-side circuit, and the other end is connected to a potential such as a GND potential in a low-side circuit. A preferable target potential in the high-side circuit to which the one end of the RFP is to be connected is determined depending on an object to be considered.

For example, when the RFP is used as a voltage-division resistor so as to detect an intermediate potential of a half-bridge circuit, the RFP is more preferably connected directly to the VS potential than connected to the VB potential. In addition, when a p⁻-type slit region for isolating the HVNMOS from the HVJT is provided, the RFP arranged over the slit region is preferably connected to the VS potential or the like lower than the VB potential, since a lower potential is better in order to avoid a field inversion in the slit region. On the other hand, it is better for the capacitive-coupling RFP located closest to the drain region of the HVNMOS to be connected to a high potential such as the VB potential higher than the VS potential in order to suppress an unexpected reduction in drain potential of the HVNMOS because of noise. In view of this, the semiconductor device according to the first embodiment has a configuration in which the RFP is divided into plural regions to lead a potential in the high-side circuit to vary depending on a region to be connected, so as to synchronously exhibit the respective advantages derived from the potential connections.

As illustrated in FIG. 2, the semiconductor device according to the first embodiment includes two independent RFPs, an RFP (10, 50) and an RFP 40, over the voltage blocking structure (3, 8) with the respective insulating films 71 and 72 (refer to FIG. 3) interposed. The RFP (10, 50) and the RFP 40 each have a function to achieve a uniform potential distribution of the high voltage applied inside the HVIC using a minute current, thereby ensuring a stable breakdown voltage. Although not illustrated, the semiconductor device may include the level-shift resistors R1 and R2 each implemented by a polysilicon layer over the well region 2 with the insulating film 71 interposed.

The RFP (10, 50) implements the resistor R7 illustrated in FIG. 1, and has a spiral planar pattern so as to surround the circumference of the well region 2 provided with the high-side circuit 102. A width of the RFP (10, 50) in a direction perpendicular to the extending direction of the spiral of the RFP (10, 50) is set to about one micrometer, for example, but can be changed as appropriate. A gap between the spiral lines adjacent to each other in the direction perpendicular to the extending direction of the spiral of the RFP (10, 50) is set to about one micrometer, for example, but can be changed as appropriate.

While FIG. 2 illustrates the case in which the RFP (10, 50) is formed into about a five-round spiral shape, the number of the rounds (the wound number) of the RFP (10, 50) can be changed as appropriate. The wound number of the RFP (10, 50) can be determined depending on the width of the voltage blocking region 8 in the direction perpendicular to the extending direction of the spiral of the RFP (10, 50), for example.

FIG. 2 illustrates the case in which the RFP (10, 50) has a left-handed spiral wound in the counterclockwise direction from the inner circumference on the high-potential side to the outer circumference on the low-potential side, but the RFP (10, 50) may have a right-handed spiral wound in the clockwise direction instead. Further, FIG. 2 illustrates the case in which the RFP (10, 50) has a substantially rectangular outline, but the outline of the RFP (10, 50) may have any other shape. The outline of the RFP (10, 50) may have a substantially oval shape or a substantially racetrack-like shape.

An end part 10a on the inner circumferential side of the RFP (10, 50) is electrically connected to the contact region 2a, which is a semiconductor region of n⁺-type, electrically connected to the high-side circuit 102. The VB potential is applied to the contact region 2a. An end part 10b on the outer circumferential side of the RFP (10, 50) is electrically connected to the contact region 4, which is a semiconductor region of p⁺-type. The ground potential (the GND potential) is applied to the contact region 4. The end part 10a on the inner circumferential side of the RFP (10, 50) is located on the high-potential side, and the end part 10b on the outer circumferential side of the RFP (10, 50) is located on the low-potential side.

The RFP (10, 50) is located closest to the drain region 23a of the level shifter 20a, among all the RFPs included in the semiconductor device according to the first embodiment. The RFP (10, 50) is arranged closer to the drain region 23a of the level shifter 20a than the RFP 40. The RFP (10, 50) is separated from the drain region 23a of the level shifter 20a by a predetermined distance d1 in the planar view of FIG. 2. The predetermined distance d1 in the region in which the RFP (10, 50) is opposed to the drain region 23a can be constant, or may vary instead.

The RFP (10, 50) includes a resistance part 10, and connection parts 50 provided at an upper level than the resistance part 10. The resistance part 10 implements a large area of the RFP (10, 50), and includes a part closest to the drain region 23a of the level shifter 20a. The resistance part 10 is partly cut off for each round of the RFP (10, 50) so that the connection parts 50 are provided at the respective cut parts. The plural connection parts 50 each have a straight planar pattern to extend parallel to each other. The respective ends on both sides of the plural connection parts 50 are electrically connected to the cut end parts of the resistance part 10. FIG. 2 schematically indicates the respectively connection parts 50 by the solid lines, and schematically indicates the connected points between the respective connection parts 50 and the resistance part 10 by the black dots.

The RFP 40 is provided at a position overlapping with the respective connection parts 50. The RFP 40 has a meandering planar pattern across the voltage blocking structure (3, 8). While FIG. 2 illustrates the case in which the respective turnover parts of the RFP 40 are opposed to the cut end parts of the resistance part 10, the turnover parts may be shifted from the cut end parts of the resistance part 10. The number of the turnover parts of the RFP 40 can be determined as appropriate.

The RFP 40 implements the voltage-division resistor 113 illustrated in FIG. 1, and has a function of detecting the VS potential that is the intermediate potential of the half-bridge circuit. An end part 40a on the inner side of the RFP 40 is electrically connected to the p-type well region 5, and is applied with the VS potential. An end part 40b on the outer side of the RFP 40 is electrically connected to the contact region 4, and is applied with the GND potential. The end part 40a on the inner side of the RFP 40 is located on the high-potential side, and the end part 40b on the outer side of the RFP 40 is located on the low-potential side.

A voltage-division point 40c is provided between the end part 40a on the inner side and the end part 40b on the outer side of the RFP 40. The voltage-division point 40c is electrically connected to the low-side circuit 101. A part of the RFP 40 on the inside of the voltage-division point 40c corresponds to the resistor R3 illustrated in FIG. 1, and a part of the RFP 40 on the outside of the voltage-division point 40c corresponds to the resistor R4 illustrated in FIG. 1. The low-side circuit 101 may monitor a potential of the voltage-division point 40c so as to stop driving the power conversion part 200 or output an alert when the potential of the voltage-division point 40c exceeds a first predetermined threshold value or falls below a second predetermined threshold value.

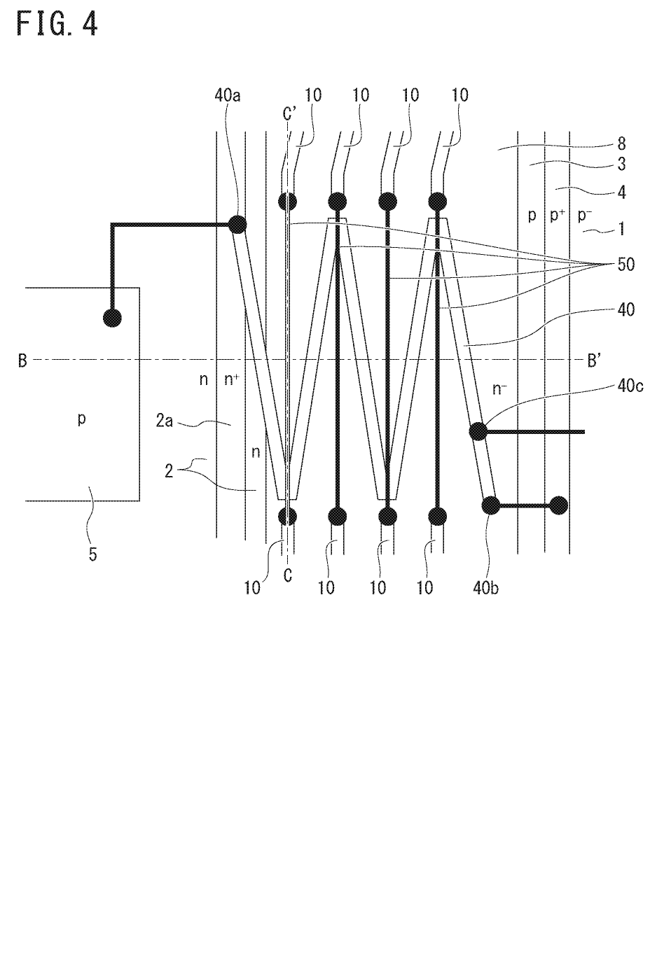

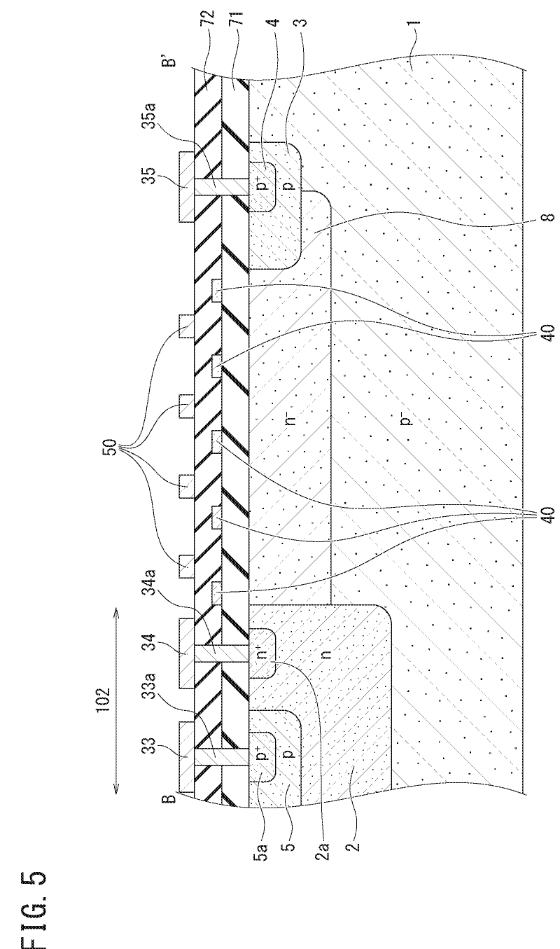

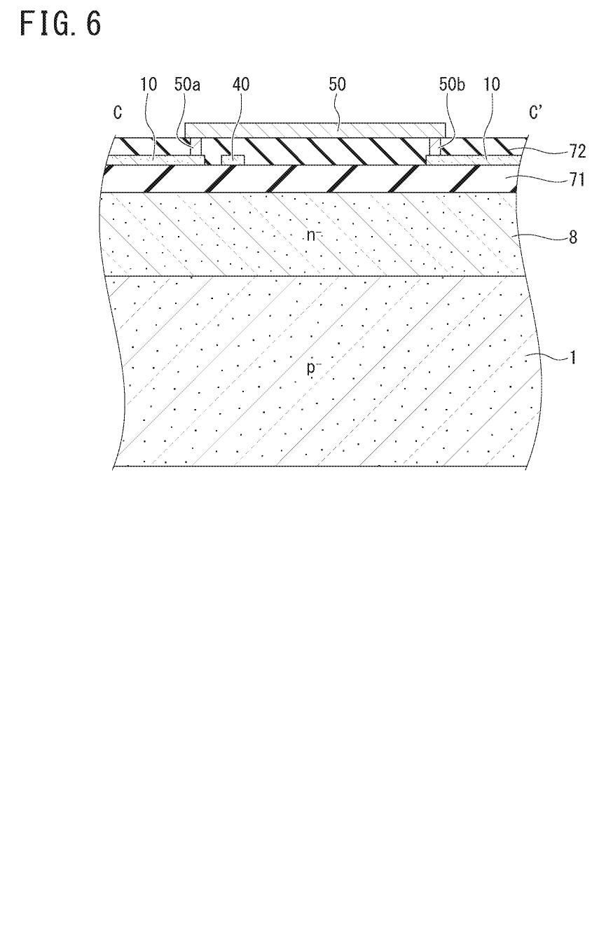

FIG. 4 is an enlarged plan view illustrating the part in which the connection parts 50 of the RFP (10, 50) and the RFP 40 illustrated in FIG. 2 overlap with each other. FIG. 4 schematically indicates the connection parts 50 by the solid lines, and schematically indicates the connected points between the respective connection parts 50 and the resistance part 10 by the black dots. FIG. 5 is a cross-sectional view taken along line B-B’ in FIG. 4, and FIG. 6 is a cross-sectional view taken along line C-C’ in FIG. 4.

As illustrated in FIG. 5, the p-type well region 5 is provided on the top surface side of the n-type well region 2. A contact region (a pickup region) 5a of p⁺-type having a higher impurity concentration than the well region 5 is provided on the top surface side of the well region 5. FIG. 2 and FIG. 4 each omit the illustration of the contact region 5a. A VS electrode 33 to which the VS potential is applied is electrically connected to the contact region 5a through a via 33a made of metal, for example, provided in an opening (a contact hole) formed in the insulating film 71 and the insulating film 72.

The contact region (the pickup region) 2a of n⁺-type having a higher impurity concentration than the n-type well region 2 is provided on the top surface side of the well region 2. A VB electrode 34 to which the VB potential is applied is electrically connected to the contact region 2a through a via 34a made of metal, for example, provided in an opening (a contact hole) formed in the insulating film 71 and the insulating film 72.

The contact region (the pickup region) 4 of p⁺-type having a higher impurity concentration than the voltage blocking region 3 is provided on the top surface side of the voltage blocking region 3. A GND electrode 35 to which the GND potential is applied is electrically connected to the contact region 4 through a via 35a made of metal, for example, provided in an opening (a contact hole) formed in the insulating film 71 and the insulating film 72.

As illustrated in FIG. 5 and FIG. 6, the RFP 40 is provided on the top surface side of the insulating film 71 over the voltage blocking region 8. The RFP 40 is a thin-film resistance layer including polysilicon doped with p-type impurities or n-type impurities, for example. The RFP 40 has an impurity concentration set in a range of about 1 × 10¹⁷ cm⁻³ or higher and 1 × 10²⁰ cm⁻³ or lower, for example. The RFP 40 has a sheet resistance set in a range of about 1 kΩ/sq or higher and 10 kΩ/sq or lower, for example.

As illustrated in FIG. 6, the resistance part 10 of the RFP (10, 50) is provided separately from the RFP 40 on the top surface side of the insulating film 71 at the same level as the RFP 40 over the voltage blocking region 8. The resistance part 10 may include the same material as the RFP 40 so as to be formed simultaneously with the RFP 40 in the same step. The resistance part 10 is a thin-film resistance layer including polysilicon doped with p-type impurities or n-type impurities, for example. The resistance part 10 has an impurity concentration set in a range of about 1 × 1017 cm?3 or higher and 1 × 1020 cm?3 or lower, for example. The resistance part 10 has a sheet resistance set in a range of about 1 k?/sq or higher and 10 k?/sq or lower, for example.

As illustrated in FIG. 5 and FIG. 6, the connection parts 50 of the RFP (10, 50) are provided on the top surface side of the insulating film 72 over the voltage blocking region 8. The connection parts 50 may be provided on the top surface side of an insulating film (not illustrated) arranged over the insulating film 72. The connection parts 50 are made of metal mainly including aluminum (Al) or copper (Cu), for example. The connection parts 50 may include the same material as the source electrode 31 and the drain electrode 32 in the level shifter 20a, so as to be formed simultaneously with the source electrode 31 and the drain electrode 32 in the same step. The connection parts 50 may include material, such as polysilicon, different from that included in the source electrode 31 and the drain electrode 32.

As illustrated in FIG. 6, both ends of the respective connection parts 50 are located to overlap with the separated end parts of the resistance part 10. The both ends of the respective connection parts 50 are electrically connected to the separated end parts of the resistance part 10 through vias 50a and 50b made of metal, for example, provided in openings (contact holes) formed in the insulating film 72. The resistance part 10 and the respective connection parts 50 are thus connected to each other in series.

The semiconductor device according to the first embodiment has the configuration as described above in which the field plate on the voltage blocking structure (3, 8) is implemented by the two independent RFPs of the RFP (10, 50) and the RFP 40. The respective end parts 10a and 40a of the RFP (10, 50) and the RFP 40 are electrically connected to the different semiconductor regions electrically connected to the high-side circuit 102. In particular, the end part 10a on the inner circumferential side of the RFP (10, 50) is electrically connected to the n-type well region 2 and the VB potential, and the end part 40a on the inner side of the RFP 40 is electrically connected to the p-type well region 5 and the VS potential. This configuration can synchronously exhibit the respective advantages of the RFP (10, 50) and the RFP 40 connected to the targets different from each other.

For example, the RFP (10, 50) having the end part 10a electrically connected to the n-type well region 2 and the VB potential is arranged closer to the drain region 23a of the level shifter 20a than the RFP 40 so as to be led to capacitive coupling. This can effectively avoid an unexpected reduction in drain potential of the level shifter 20a because of noise.

In addition, the RFP 40 having the end part 40a electrically connected to the p-type well region 5 and the VS potential is used as the voltage-division resistor 113 (as a sense resistor) so as to detect the potential of the high-side circuit 102. This configuration can directly detect the VS potential that is the intermediate potential of the half-bridge circuit.

### SECOND EMBODIMENT

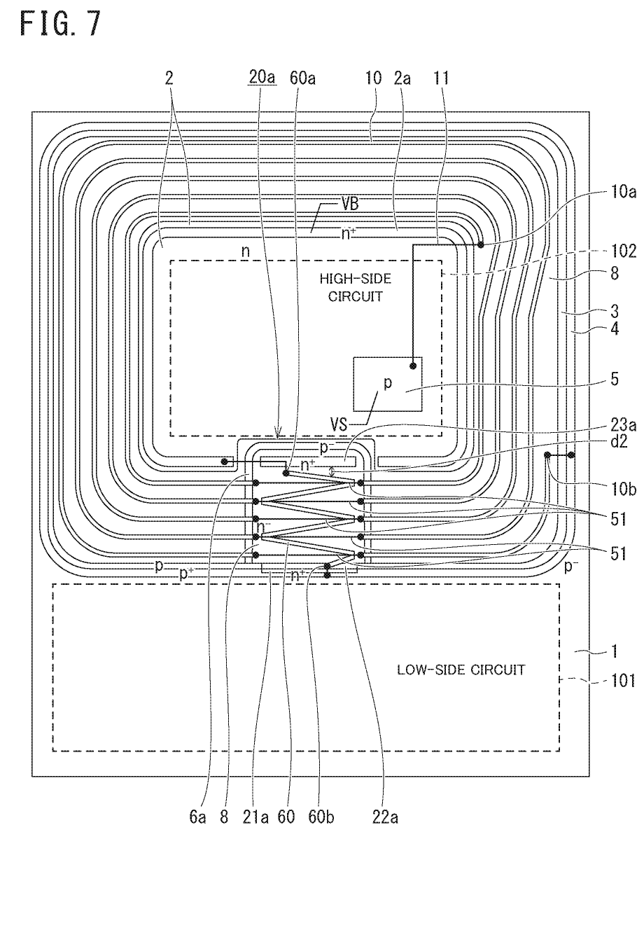

FIG. 7 is a plan view illustrating a semiconductor device according to a second embodiment. The semiconductor device according to the second embodiment differs from the semiconductor device according to the first embodiment in including an RFP (10, 51) and an RFP 60, which are two independent RFPs, as illustrated in FIG. 7.

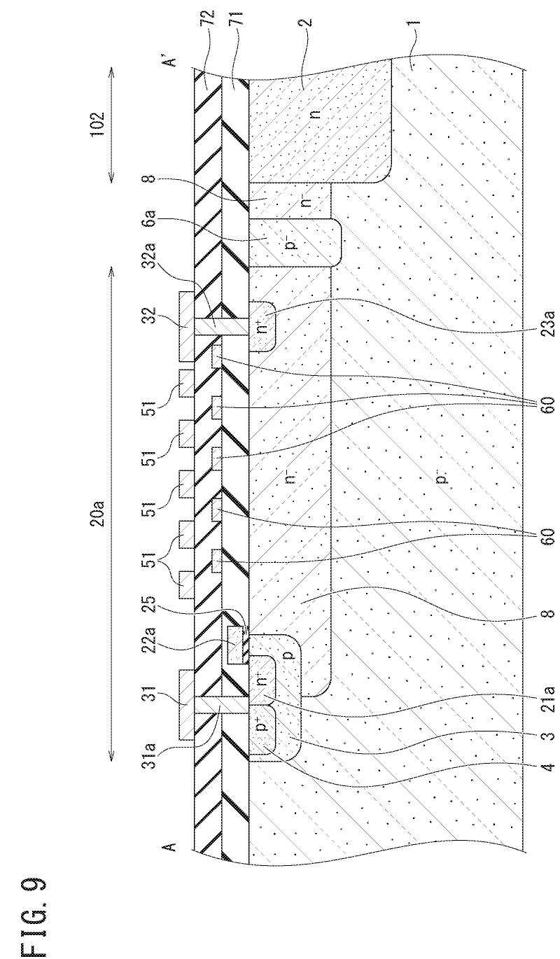

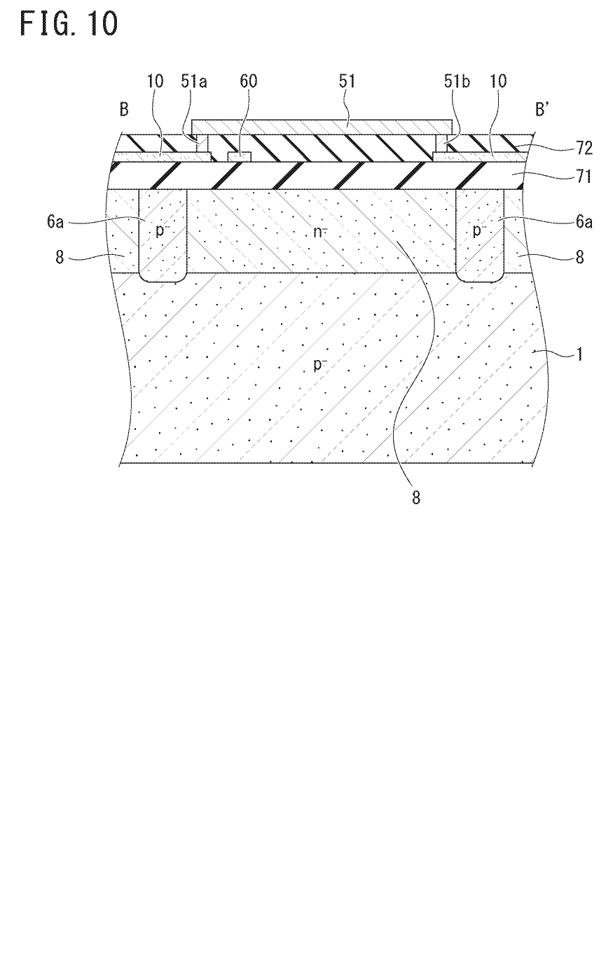

The RFP (10, 51) and the RFP 60 are provided over the voltage blocking structure (3, 8) with the respective insulating films 71 and 72 interposed (refer to FIG. 9 and FIG. 10). The RFP (10, 51) and the RFP 60 each have a function to achieve a uniform potential distribution of the high voltage applied inside the HVIC using a minute current, thereby ensuring a stable breakdown voltage.

The RFP (10, 51) has a spiral planar pattern so as to surround the circumference of the well region 2 provided with the high-side circuit 102. A width of the RFP (10, 51) in a direction perpendicular to the extending direction of the spiral of the RFP (10, 51) is set to about one micrometer, for example, but can be changed as appropriate. A gap between the spiral lines adjacent to each other in the direction perpendicular to the extending direction of the spiral of the RFP (10, 51) is set to about one micrometer, for example, but can be changed as appropriate.

While FIG. 7 illustrates the case in which the RFP (10, 51) is formed into a five-round spiral shape, the number of the rounds (the wound number) of the RFP (10, 51) can be changed as appropriate. The wound number of the RFP (10, 51) can be determined depending on the width of the voltage blocking region 8 in the direction perpendicular to the extending direction of the spiral of the RFP (10, 51), for example.

FIG. 7 illustrates the case in which the RFP (10, 51) has a left-handed spiral wound in the counterclockwise direction toward the outer circumference of the RFP (10, 51), but the RFP (10, 51) may have a right-handed spiral wound in the clockwise direction instead. Further, FIG. 7 illustrates the case in which the RFP (10, 51) has a substantially rectangular outline, but the outline of the RFP (10, 51) may have any other shape. The outline of the RFP (10, 51) may have a substantially oval shape or a substantially racetrack-like shape.

The well region 5, which is a semiconductor region of p-type, is electrically connected to the end part 10a on the inner circumferential side of the RFP (10, 51) to which the VS potential is applied. The contact region 4, which is a semiconductor region of p⁺-type, is electrically connected to the end part 10b on the outer circumferential side of the RFP (10, 51) to which the ground potential (the GND potential) is applied.

The RFP (10, 51) includes the resistance part 10, and connection parts 51 provided at an upper level than the resistance part 10. The resistance part 10 implements a large area of the RFP (10, 51). The resistance part 10 overlaps with the slit region 6a surrounding the circumference of the level shifter 20a, and includes a part passing through (across) the upper side of the slit region 6a. The resistance part 10 is partly cut off for each round of the RFP (10, 51) at the position overlapping with the level shifter 20a so that the connection parts 51 are provided at the respective cut parts in the planar view of FIG. 7. The plural connection parts 51 each have a straight planar pattern to extend parallel to each other. The respective ends on both sides of the plural connection parts 51 are electrically connected to the cut end parts of the resistance part 10. FIG. 7 schematically indicates the respectively connection parts 51 by the solid lines, and schematically indicates the connected points between the respective connection parts 51 and the resistance part 10 by the black dots.

The RFP 60 is provided across the voltage blocking structure (3, 8) at a position overlapping with the level shifter 20a within a region surrounded by the p⁻-type slit region 6a. The RFP 60 has a meandering planar pattern. The n⁺-type contact region 2a is electrically connected to an end part 60a on the inner side of the RFP 60 to which the VB potential is applied. The contact region 4 is electrically connected to an end part 60b on the outer side of the RFP 60 to which the GND potential is applied.

The RFP 60 is located closest to the drain region 23a of the level shifter 20a, among all the RFPs included in the semiconductor device according to the second embodiment. The RFP 60 is arranged closer to the drain region 23a of the level shifter 20a than the RFP (10, 51). The RFP 60 is separated from the drain region 23a of the level shifter 20a by a predetermined distance d2 in the planar view of FIG. 7. The predetermined distance d2 in the region in which the RFP 60 is opposed to the drain region 23a may vary depending on the meandering planar pattern of the RFP 60. The RFP 60 is more preferably arranged closer to the drain electrode 32 of the level shifter 20a than the RFP (10, 51). Leading the RFP 60 to capacitive coupling with the drain electrode 32 can further enhance the effect of effectively avoiding an unexpected reduction in drain potential of the level shifter 20a because of noise.

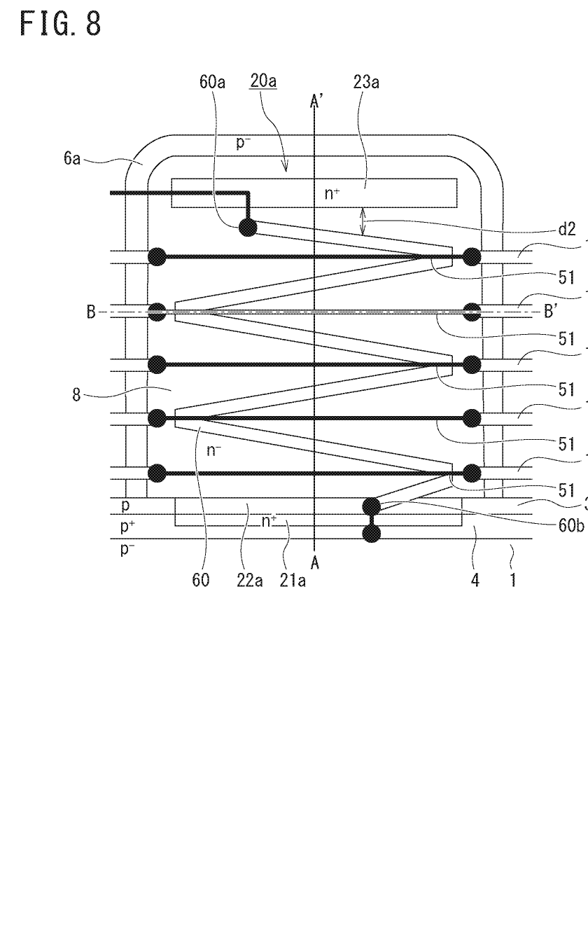

FIG. 8 is an enlarged plan view illustrating the part in which the connection parts 51 of the RFP (10, 51) and the RFP 60 illustrated in FIG. 7 overlap with each other. FIG. 8 schematically indicates the connection parts 51 by the solid lines, and schematically indicates the connected points between the respective connection parts 51 and the resistance part 10 by the black dots.

FIG. 9 is a cross-sectional view taken along line A-A’ in FIG. 8, and FIG. 10 is a cross-sectional view taken along line B-B’ in FIG. 8. As illustrated in FIG. 9 and FIG. 10, the RFP 60 is provided on the top surface side of the insulating film 71 over the voltage blocking region 8. The RFP 60 is a thin-film resistance layer including polysilicon doped with p-type impurities or n-type impurities, for example. The RFP 60 has an impurity concentration set in a range of about 1 × 10¹⁷ cm⁻³ or higher and 1 × 10²⁰ cm⁻³ or lower, for example. The RFP 60 has a sheet resistance set in a range of about 1 kΩ/sq or higher and 10 kΩ/sq or lower, for example.

As illustrated in FIG. 10, the resistance part 10 of the RFP (10, 51) is provided separately from the RFP 60 on the top surface side of the insulating film 71 at the same level as the RFP 60 over the voltage blocking region 8. The resistance part 10 may include the same material as the RFP 60 so as to be formed simultaneously with the RFP 60 in the same step. The resistance part 10 is a thin-film resistance layer including polysilicon doped with p-type impurities or n-type impurities, for example. The resistance part 10 has an impurity concentration set in a range of about 1 × 10¹⁷ cm⁻³ or higher and 1 × 10²⁰ cm⁻³ or lower, for example. The resistance part 10 has a sheet resistance set in a range of about 1 kΩ/sq or higher and 10 kΩ/sq or lower, for example.

As illustrated in FIG. 9 and FIG. 10, the connection parts 51 of the RFP (10, 51) are provided on the top surface side of the insulating film 72 over the voltage blocking region 8. The connection parts 51 may be provided on the top surface side of an insulating film (not illustrated) arranged over the insulating film 72. The connection parts 51 are made of metal mainly including aluminum (Al) or copper (Cu), for example. The connection parts 51 may include the same material as the source electrode 31 and the drain electrode 32 in the level shifter 20a, so as to be formed simultaneously with the source electrode 31 and the drain electrode 32 in the same step. The connection parts 51 may include material, such as polysilicon, different from that included in the source electrode 31 and the drain electrode 32.

As illustrated in FIG. 10, both ends of the respective connection parts 51 are located to overlap with the separated end parts of the resistance part 10. The both ends of the connection parts 51 are electrically connected to the separated end parts of the resistance part 10 through vias 51a and 51b made of metal, for example, provided in openings (contact holes) formed in the insulating film 72. The resistance part 10 and the connection parts 51 are thus connected to each other in series. The other configurations of the semiconductor device according to the second embodiment are substantially the same as those of the semiconductor device according to the first embodiment, and overlapping explanations are not repeated below.

The semiconductor device according to the second embodiment has the configuration as described above in which the field plate on the voltage blocking structure (3, 8) is implemented by the two independent RFPs of the RFP (10, 51) and the RFP 60. The respective end parts 10a and 60a of the RFP (10, 51) and the RFP 60 are electrically connected to the semiconductor regions different from each other. In particular, the end part 10a of the RFP (10, 51) is electrically connected to the p-type well region 5 and the VS potential, and the end part 60a of the RFP 60 is electrically connected to the n-type well region 2 and the VB potential. This configuration can synchronously exhibit the respective advantages of the RFP (10, 51) and the RFP 60 connected to the targets different from each other.

For example, the RFP 60 having the end part 60a electrically connected to the n-type well region 2 and the VB potential is arranged closer to the drain region 23a of the level shifter 20a than the RFP (10, 51) so as to be led to capacitive coupling. This can effectively avoid an unexpected reduction in drain potential of the level shifter 20a because of noise.

If the p⁻-type slit region 6a is led to a field inversion, a parasitic n-type MOSFET starts to operate in which the slit region 6a serves as a channel while the regions in the voltage blocking region 8 interposing the slit region 6a serve as a source and a drain. The configuration according to the present embodiment, in which the RFP (10, 51) having the end part 10a electrically connected to the p-type well region 5 and the VS potential is provided to overlap with the p⁻-type slit region 6a, can avoid such a field inversion of the slit region 6a.

### THIRD EMBODIMENT

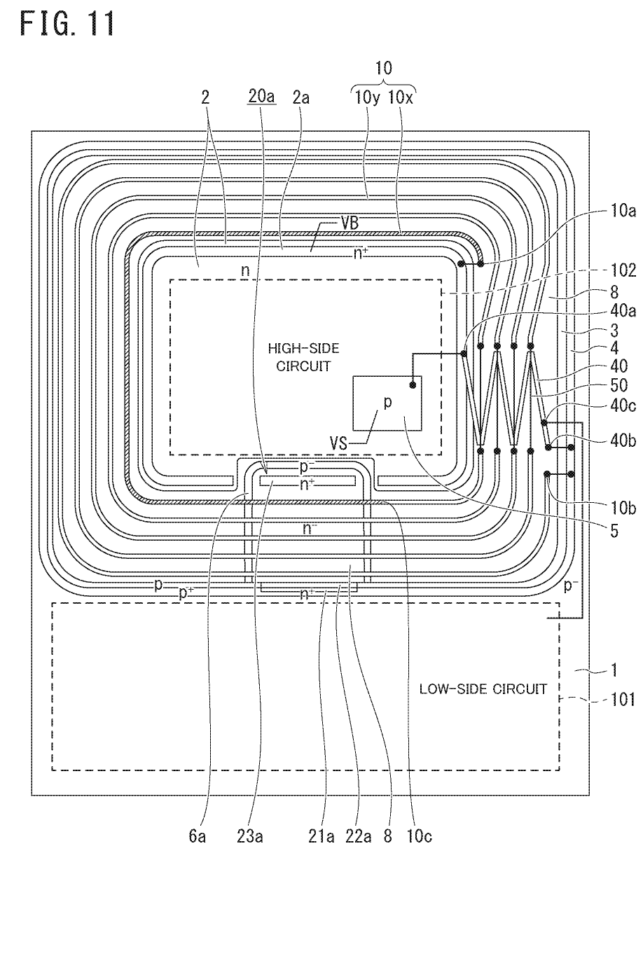

FIG. 11 is a plan view illustrating a semiconductor device according to a third embodiment. The semiconductor device according to the third embodiment has the same configuration as the semiconductor device according to the first embodiment in including the two independent RFPs, the RFP (10, 50) and the RFP 40, as illustrated in FIG. 11. The semiconductor device according to the third embodiment differs from the semiconductor device according to the first embodiment in that the resistance part 10 of the RFP (10, 50) includes a resistance part (a low-resistance part) 10x and a resistance part (a high-resistance part) 10y having a higher resistance than the low-resistance part 10x. FIG. 11 schematically indicates the low-resistance part 10x with diagonal hatching attached.

The low-resistance part 10x includes an area from the end part 10a on the inner side of the RFP (10, 50) to at least a region passing through (across) the upper side of a pair of the opposed parts of the slit region 6a interposing the level shifter 20a in the extending direction of the low-resistance part 10x in the planar view of FIG. 11. The low-resistance part 10x includes a part closest to the drain region 23a of the level shifter 20a. The low-resistance part 10x is located closer to the drain region 23a of the level shifter 20a than the high-resistance part 10y.

The low-resistance part 10x has a sheet resistance set in a range of about 100 Ω/sq or higher and 1 kΩ/sq or lower, for example. The low-resistance part 10x has a higher impurity concentration than the high-resistance part 10y. The impurity concentration of the low-resistance part 10x may be the same as that of a contact part of the end part 10a on the inner side of the RFP (10, 50) and a contact part of the end part 10b on the outer side of the RFP (10, 50). The low-resistance part 10x can be formed by ion implantation of p-type impurities or n-type impurities with a higher total dose than that of the high-resistance part 10y.

The high-resistance part 10y includes an area from a boundary position 10c with the low-resistance part 10x to the end part 10b on the outer side of the RFP (10, 50). The high-resistance part 10y has a sheet resistance set in a range of about 1 kΩ/sq or higher and 10 kΩ/sq or lower, for example. The other configurations of the semiconductor device according to the third embodiment are substantially the same as those of the semiconductor device according to the first embodiment, and overlapping explanations are not repeated below.

The configuration of the semiconductor device according to the third embodiment can synchronously exhibit the respective advantages of the RFP (10, 50) and the RFP 40 connected to the targets different from each other, as in the case of the first embodiment. The semiconductor device according to the third embodiment also has the configuration in which the RFP (10, 50) includes the low-resistance part 10x and the high-resistance part 10y, and in which the low-resistance part 10x having a small voltage drop from the VB potential is located closest to the drain region 23a of the level shifter 20a. This configuration can avoid a reduction in drain potential of the level shifter 20a more effectively.

### FOURTH EMBODIMENT

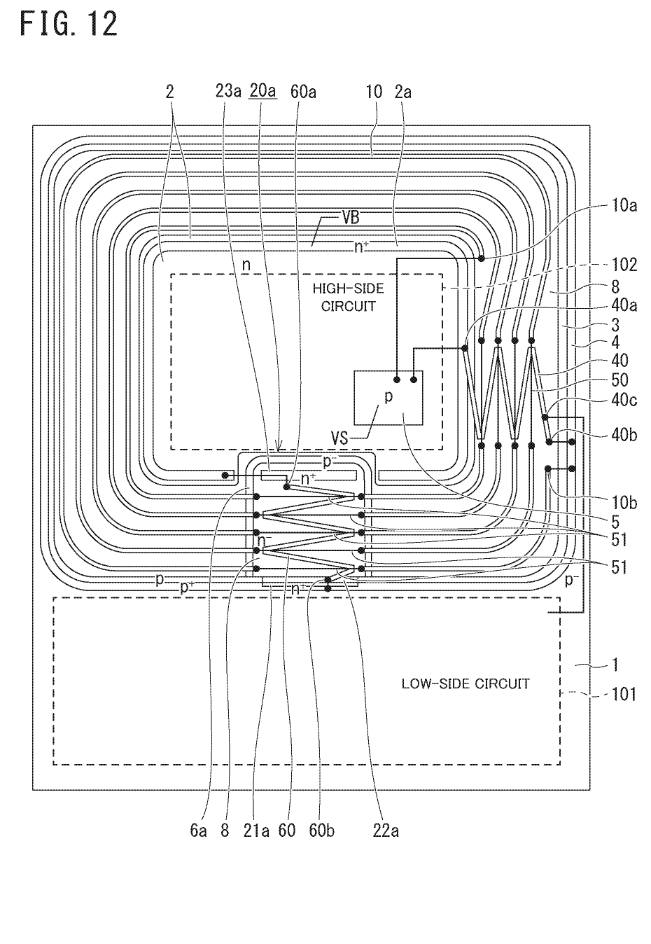

FIG. 12 is a plan view illustrating a semiconductor device according to a fourth embodiment. The semiconductor device according to the fourth embodiment differs from the semiconductor device according to the first embodiment in including three independent RFPs, an RFP (10, 50, 51), an RFP 40, and an RFP 60, as field plates on the voltage blocking structure (3, 8), as illustrated in FIG. 12.

The RFP (10, 50, 51) has substantially the same configuration as the RFP (10, 51) in the semiconductor device according to the second embodiment illustrated in FIG. 7, but differs from the RFP (10, 51) in further including the connection parts 50. The RFP (10, 50, 51) has a spiral planar pattern. The p-type well region 5 is electrically connected to the end part 10a on the inner side of the RFP (10, 50, 51) to which the VS potential is applied. The p⁺-type contact region 4 is electrically connected to the end part 10b on the outer side of the RFP (10, 50, 51) to which the GND potential is applied.

The RFP (10, 50, 51) includes the resistance part 10, and the connection parts 50 and 51 provided at an upper level than the resistance part 10. The resistance part 10 is provided to pass through the upper side of the p⁻-type slit region 6a. The connection parts 50 are provided to overlap with the RFP 40. The connection parts 51 are provided to overlap with the RFP 60 within a region surrounded by the slit region 6a.

The RFP 40 has substantially the same configuration as the RFP 40 in the semiconductor device according to the first embodiment illustrated in FIG. 2. The RFP 40 implements the voltage-division resistor 113 and has a function of detecting the VS potential. The well region 5 is electrically connected to the end part 40a on the inner side of the RFP 40 to which the VS potential is applied. The contact region 4 is electrically connected to the end part 40b on the outer side of the RFP 40 to which the GND potential is applied. The voltage-division point 40c of the RFP 60 is electrically connected to the low-side circuit 101.

The RFP 60 has substantially the same configuration as the RFP 60 in the semiconductor device according to the second embodiment illustrated in FIG. 7. The end part 60a on the inner side of the RFP 60 to which the VB potential is applied is electrically connected to the contact region 2a. The end part 60b on the outer side of the RFP 60 to which the GND potential is applied is electrically connected to the contact region 4. The RFP 60 is arranged at a position closest to the drain region 23a of the level shifter 20a. The other configurations of the semiconductor device according to the fourth embodiment are substantially the same as those of the semiconductor device according to the first embodiment, and overlapping explanations are not repeated below.

The semiconductor device according to the fourth embodiment has the configuration as described above in which the field plate on the voltage blocking structure (3, 8) is implemented by the three independent RFPs of the RFP (10, 50, 51), the RFP 40, and the RFP 60. The respective end parts 10a and 40a of the RFP (10, 50, 51) and the RFP 40 and the end part 60a of the RFP 60 are electrically connected to the semiconductor regions different from each other. In particular, the respective end parts 10a and 40a of the RFP (10, 50, 51) and the RFP 40 are electrically connected to the p-type well region 5 and the VS potential, and the end part 60a of the RFP 60 is electrically connected to the n-type well region 2 and the VB potential. This configuration can synchronously exhibit the respective advantages of the three independent RFPs of the RFP (10, 50, 51), the RFP 40, and the RFP 60.

For example, the RFP 60 having the end part 60a electrically connected to the n-type well region 2 and the VB potential is arranged at the position closest to the drain region 23a of the level shifter 20a, so as to effectively avoid a reduction in drain potential of the level shifter 20a. In addition, the RFP 40 having the end part 40a electrically connected to the p-type well region 5 and the VS potential is used as the voltage-division resistor 113 to detect the intermediate potential of the half-bridge circuit, so as to directly detect the VS potential that is the intermediate potential of the half-bridge circuit. The RFP (10, 50, 51) provided with the volage-division point can be used as the voltage-division resistor 113. However, such a voltage-division resistor causes large parasitic capacitance and needs to a longer detection time because a resistance value and an area are required to be determined in view of field plate effects to be ensured in the entire voltage blocking structure. Providing the RFP 40 connected to the VS potential independently of the RFP (10, 50, 51) can arrange the voltage-division resistor having a preferable resistance value and parasitic capacitance in view of a detection time and a consumption current. Further, the provision of the RFP (10, 50, 51) can exhibit the field plate effects in the entire voltage blocking structure, and can also avoid a field inversion of the p ⁻-type slit region 6a when the RFP (10, 50, 51) is provided to overlap with the slit region 6a.

### FIFTH EMBODIMENT

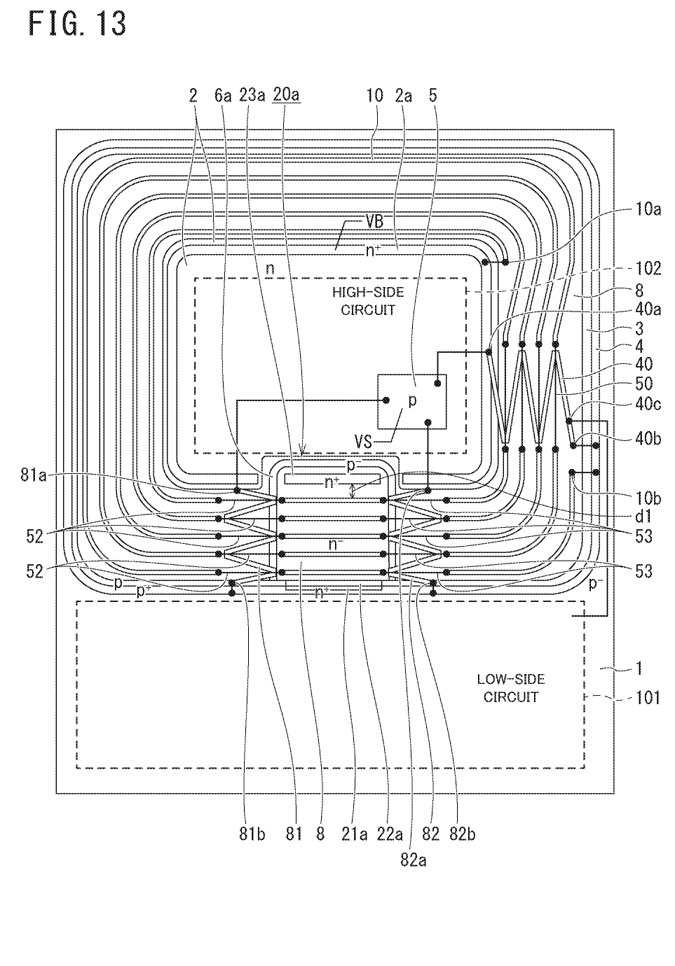

FIG. 13 is a plan view illustrating a semiconductor device according to a fifth embodiment. The semiconductor device according to the fifth embodiment differs from the semiconductor device according to the first embodiment illustrated in FIG. 2 in including four independent RFPs, an RFP (10, 50, 52, 53), an RFP 40, an RFP 81, and an RFP 82, as field plates on the voltage blocking structure (3, 8), as illustrated in FIG. 13.

The RFP (10, 50, 52, 53) has substantially the same configuration as the RFP (10, 50) in the semiconductor device according to the first embodiment illustrated in FIG. 2, but differs from the RFP (10, 50) in further including connection parts 52 and 53. The RFP (10, 50, 52, 53) has a spiral planar pattern. The n⁺-type contact region 2a is electrically connected to the end part 10a on the inner side of the RFP (10, 50, 52, 53) to which the VB potential is applied. The p⁺-type contact region 4 is electrically connected to the end part 10b on the outer side of the RFP (10, 50, 52, 53) to which the GND potential is applied. The RFP (10, 50, 52, 53) is arranged at a position closest to the drain region 23a of the level shifter 20a among the four RFPs.

The RFP (10, 50, 52, 53) includes the resistance part 10, and the connection parts 50, 52, and 53 provided at an upper level than the resistance part 10. FIG. 13 schematically indicates the respective connection parts 50, 52, and 53 by the solid lines, and schematically indicates the connected points between the respective connection parts 50, 52, and 53 and the resistance part 10 by the black dots. The resistance part 10 includes a part closest to the drain region 23a of the level shifter 20a. The resistance part 10 is not provided over the p⁻-type slit region 6a. The respective connection parts 52 and 53 are provided to pass through the upper side of the slit region 6a. The connection parts 50 are arranged to overlap with the RFP 40. The connection parts 52 are arranged to overlap with the RFP 81. The connection parts 53 are arranged to overlap with the RFP 82.

The RFP 40 has substantially the same configuration as the RFP 40 in the semiconductor device according to the first embodiment illustrated in FIG. 2. The RFP 40 implements the voltage-division resistor 113 and has a function of detecting the VS potential. The RFP 40 is located at a position at which the resistance part 10 is cur off under the connection parts 50. The well region 5 is electrically connected to the end part 40a on the inner side of the RFP 40 to which the VS potential is applied. The contact region 4 is electrically connected to the end part 40b on the outer side of the RFP 40 to which the GND potential is applied. The voltage-division point 40c of the RFP 40 is electrically connected to the low-side circuit 101.

The RFP 81 is located at a position at which the resistance part 10 is cut off under the connection parts 52. The RFP 81 has a meandering planar pattern passing across the voltage blocking structure (3, 8). The RFP 81 is arranged to pass through the upper side of the slit region 6a. The RFP 81 is located at the same level as the resistance part 10 separately from each other. The well region 5 is electrically connected to an end part 81a on the inner side of the RFP 81 to which the VS potential is applied. The contact region 4 is electrically connected to an end part 81b on the outer side of the RFP 81 to which the GND potential is applied.

The RFP 82 is located at a position at which the resistance part 10 is cur off under the connection parts 53. The RFP 82 has a meandering planar pattern passing across the voltage blocking structure (3, 8). The RFP 82 is arranged to pass through the upper side of the slit region 6a. The RFP 82 is located at the same level as the resistance part 10 separately from each other. The well region 5 is electrically connected to an end part 82a on the inner side of the RFP 82 to which the VS potential is applied. The contact region 4 is electrically connected to an end part 82b on the outer side of the RFP 82 to which the GND potential is applied. The other configurations of the semiconductor device according to the fifth embodiment are substantially the same as those of the semiconductor device according to the first embodiment, and overlapping explanations are not repeated below.

The semiconductor device according to the fifth embodiment has the configuration as described above in which the field plate on the voltage blocking structure (3, 8) is implemented by the four independent RFPs of the RFP (10, 50, 52, 53), the RFP 40, the RFP 81, and the RFP 82. The end part 10a of the RFP (10, 50, 52, 53) and the respective end parts 40a, 81a, and 82a of the RFP 40, the RFP 81, and the RFP 82 are electrically connected to the semiconductor regions different from each other. In particular, the respective end parts 40a, 81a, and 82a of the RFP 40, the RFP 81, and the RFP 82 are electrically connected to the p-type well region 5 and the VS potential, and the end part 10a of the RFP (10, 50, 52, 53) is electrically connected to the n-type well region 2 and the VB potential. This configuration can synchronously exhibit the respective advantages of the four independent RFPs of the RFP (10, 50, 52, 53), the RFP 40, the RFP 81, and the RFP 82.

For example, the RFP (10, 50, 52, 53) having the end part 10a electrically connected to the n-type well region 2 and the VB potential is arranged at the position closest to the drain region 23a of the level shifter 20a, so as to effectively avoid a reduction in drain potential of the level shifter 20a. In addition, the RFP 40 having the end part 40a electrically connected to the p-type well region 5 and the VS potential is used as the voltage-division resistor 113 to detect the intermediate potential of the half-bridge circuit, so as to directly detect the VS potential that is the intermediate potential of the half-bridge circuit. Further, the RFPs 81 and 82 having the end parts 81a and 82a electrically connected to the p-type well region 5 and the VS potential are provided to pass through the upper side of the p⁻-type slit region 6a, so as to avoid a field inversion of the slit region 6a.

### SIXTH EMBODIMENT

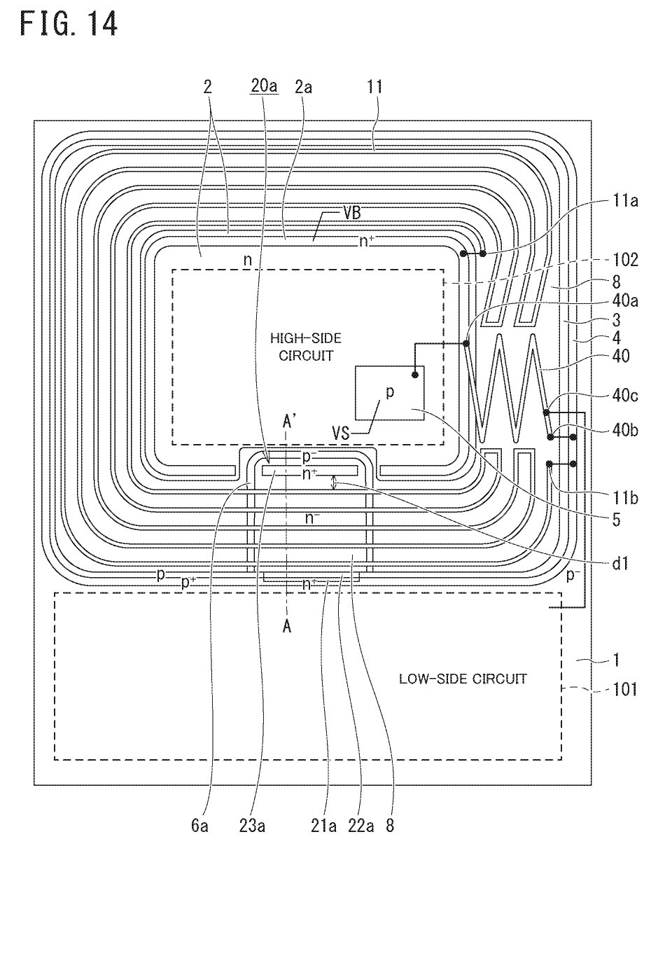

FIG. 14 is a plan view illustrating a semiconductor device according to a sixth embodiment. As illustrated in FIG. 14, the semiconductor device according to the sixth embodiment differs from the semiconductor device according to the first embodiment illustrated in FIG. 2 in including an RFP 11, which is connected to the well region 2 and the VB potential, having a meandering planar pattern surrounding the well region 2, instead of the spiral planar pattern.

The well region 2 and the VB potential are electrically connected to an end part 11a on the inner side of the RFP 11. The contact region 4 and the GND potential are electrically connected to an end part 11b on the outer side of the RFP 11. The RFP 40 is provided between the turnover parts of the RFP 11 in the meandering planar pattern. While FIG. 14 illustrates the case in which the RFP 11 is formed into a single meandering state in the planar pattern, the RFP 11 may be divided into a plurality of meandering parts in the planar pattern. The other configurations of the semiconductor device according to the sixth embodiment are substantially the same as those of the semiconductor device according to the first embodiment, and overlapping explanations are not repeated below.

The semiconductor device according to the sixth embodiment, which has the configuration in which the RFP 11 connected to the well region 2 and the VB potential has the meandering planar pattern, instead of the spiral planar pattern, can also achieve substantially the same effects as the semiconductor device according to the first embodiment.

### SEVENTH EMBODIMENT

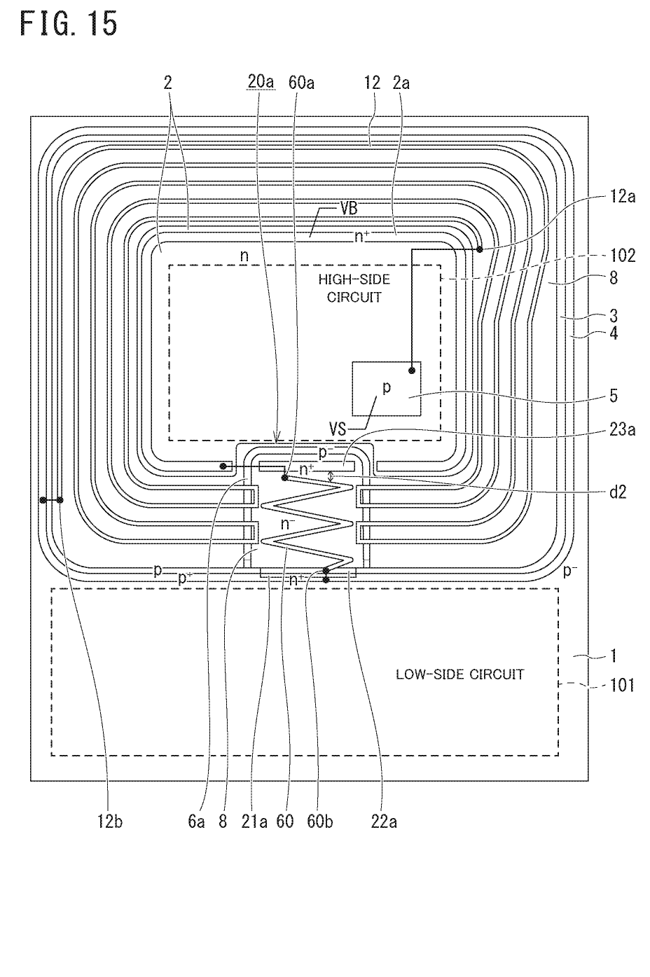

FIG. 15 is a plan view illustrating a semiconductor device according to a seventh embodiment. As illustrated in FIG. 15, the semiconductor device according to the seventh embodiment differs from the semiconductor device according to the second embodiment illustrated in FIG. 7 in including an RFP 12, which is connected to the well region 5 and the VS potential, having a meandering planar pattern surrounding the well region 2, instead of the spiral planar pattern.

The well region 5 and the VS potential are electrically connected to an end part 12a on the inner side of the RFP 12. The contact region 4 and the GND potential are electrically connected to an end part 12b on the outer side of the RFP 12. The turnover parts of the RFP 12 in the meandering planar pattern are arranged to pass through the upper side of the p⁻-type slit region 6a. The RFP 60 is provided between the respective turnover parts of the RFP 12 in the meandering planar pattern. While FIG. 15 illustrates the case in which the RFP 12 is formed into a single meandering state in the planar pattern, the RFP 12 may be divided into a plurality of meandering parts in the planar pattern. The other configurations of the semiconductor device according to the seventh embodiment are substantially the same as those of the semiconductor device according to the second embodiment, and overlapping explanations are not repeated below.

The semiconductor device according to the seventh embodiment, which has the configuration in which the RFP 12 connected to the well region 5 and the VS potential has the meandering planar pattern, instead of the spiral planar pattern, can also achieve substantially the same effects as the semiconductor device according to the second embodiment.

### EIGHTH EMBODIMENT

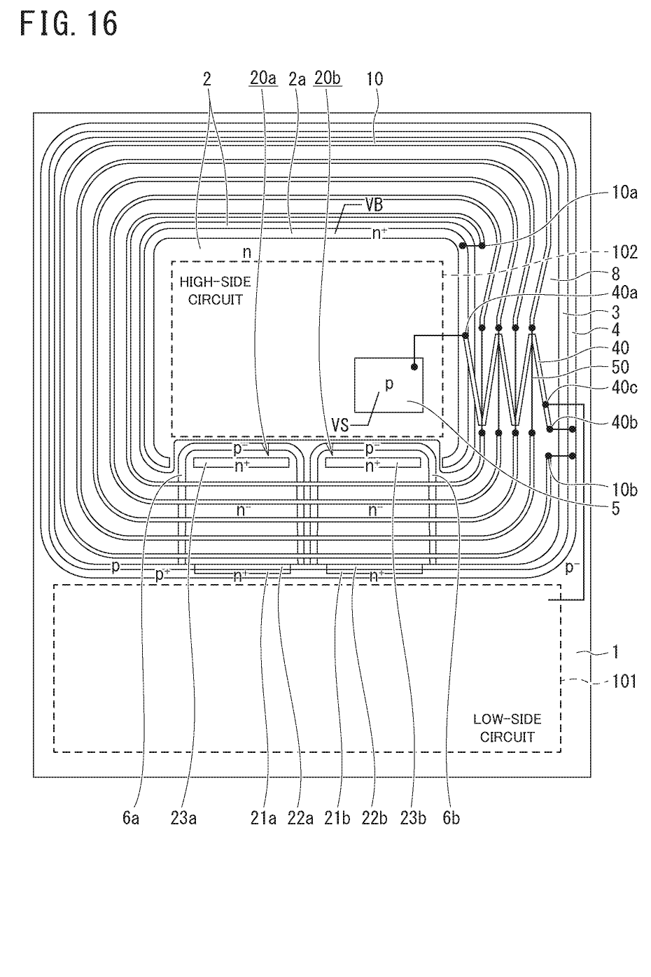

FIG. 16 is a plan view illustrating a semiconductor device according to an eighth embodiment. As illustrated in FIG. 16, the semiconductor device according to the eighth embodiment differs from the semiconductor device according to the first embodiment illustrated in FIG. 2 in including a plurality of (two) level shifters 20a and 20b provided integrally with a part of the voltage blocking structure (3, 8). The level shifters 20a and 20b are arranged next to each other on one side of the rectangular planar pattern of the voltage blocking structure (3, 8). The arranged position of the respective level shifters 20a and 20b is not limited to this case as illustrated. For example, the level shifters 20a and 20b may be arranged on the sides opposite to each other in the rectangular planar pattern of the voltage blocking structure (3, 8).

The level shifter 20b has substantially the same structure as the level shifter 20a. The level shifter 20b includes a source region 21b of n⁺-type, a gate electrode 22b, and a drain region 23b of n⁺-type. The source region 21b, the gate electrode 22b, and the drain region 23b each have a straight planar pattern to extend parallel to each other. A part of the voltage blocking region 8 interposed between the source region 21b and the drain region 23b implements a drift region of the level shifter 20b.

A slit region 6b of p⁻-type is provided so as to surround the level shifter 20b. The slit region 6b electrically isolates the level shifter 20b from the well region 2. The other configurations of the semiconductor device according to the eighth embodiment are substantially the same as those of the semiconductor device according to the first embodiment, and overlapping explanations are not repeated below.

The semiconductor device according to the eighth embodiment, which includes the plural level shifters 20a and 20b, can also achieve substantially the same effects as the semiconductor device according to the first embodiment. When the semiconductor device according to the seventh embodiment illustrated in FIG. 15 includes the two level shifters 20a and 20b, an RFP similar to the RFP 60 may be provided at a position overlapping with the level shifter 20b.

### NINTH EMBODIMENT

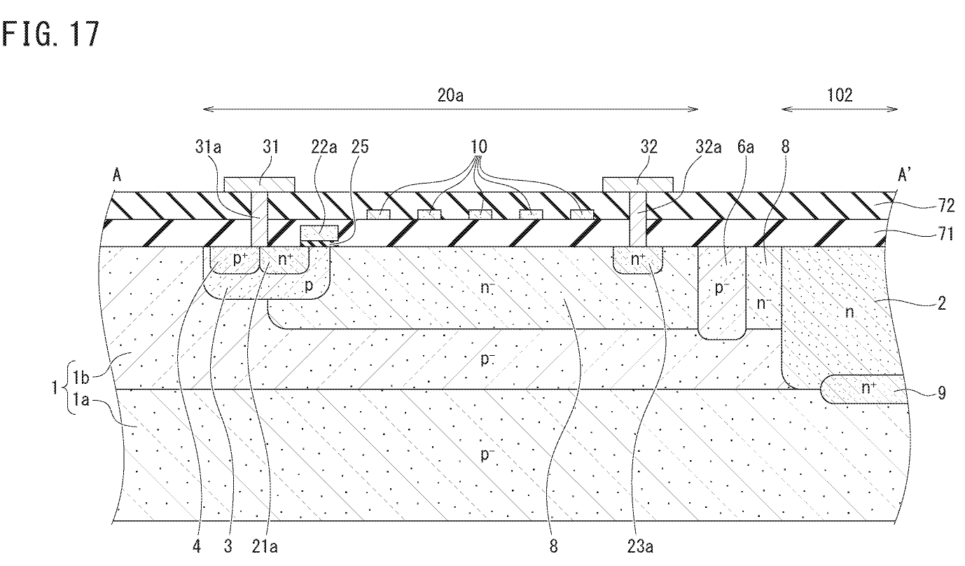

FIG. 17 is a cross-sectional view illustrating a semiconductor device according to a ninth embodiment, corresponding to the cross section of the semiconductor device according to the first embodiment illustrated in FIG. 3. As illustrated in FIG. 17, the semiconductor device according to the ninth embodiment differs from the semiconductor device according to the first embodiment illustrated in FIG. 3 in that the base body 1 includes a semiconductor substrate 1a of p⁻-type, and an epitaxial growth layer 1b of p⁻-type epitaxially grown on the semiconductor substrate 1a.

The semiconductor device according to the ninth embodiment further differs from the semiconductor device according to the first embodiment illustrated in FIG. 3 in including a buried layer 9 of n ⁺-type having a higher impurity concentration than the well region 2 so as to be in contact with the bottom surface of the well region 2. The other configurations of the semiconductor device according to the ninth embodiment are substantially the same as those of the semiconductor device according to the first embodiment, and overlapping explanations are not repeated below.

The semiconductor device according to the ninth embodiment, which has the configuration in which the base body 1 includes the p⁻-type semiconductor substrate 1a and the p⁻-type epitaxial growth layer 1b epitaxially grown on the semiconductor substrate 1a, can also achieve substantially the same effects as the semiconductor device according to the first embodiment. Further, the semiconductor device according to the ninth embodiment, which includes the n⁺-type buried layer 9 having a higher impurity concentration than the well region 2 and buried in contact with the bottom surface of the well region 2, can also achieve substantially the same effects as the semiconductor device according to the first embodiment. The configuration of the epitaxial growth substrate in the semiconductor device according to the ninth embodiment can also be applied to the respective semiconductor devices according to the second to eighth embodiments.

### TENTH EMBODIMENT

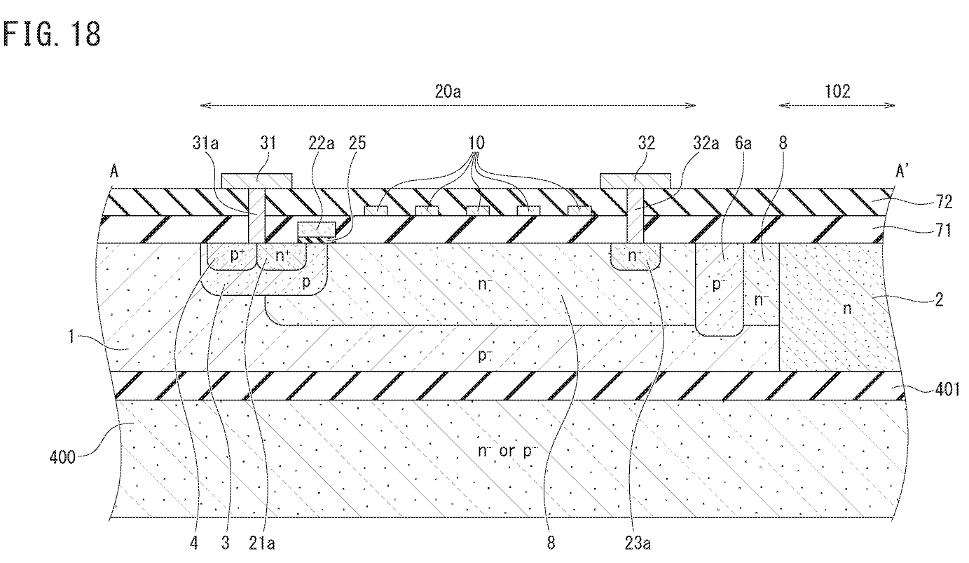

FIG. 18 is a cross-sectional view illustrating a semiconductor device according to a tenth embodiment, corresponding to the cross section of the semiconductor device according to the first embodiment illustrated in FIG. 3. As illustrated in FIG. 18, the semiconductor device according to the tenth embodiment differs from the semiconductor device according to the first embodiment illustrated in FIG. 3 in being implemented by a silicon-on-insulator (SOI) substrate.

The semiconductor device according to the tenth embodiment includes a support substrate 400 of n ⁻-type or p⁻-type. An insulating film 401 such as an oxide film is provided on the top surface side of the support substrate 400. The p⁻-type base body 1 is further provided on the top surface side of the insulating film 401. The other configurations of the semiconductor device according to the tenth embodiment are substantially the same as those of the semiconductor device according to the first embodiment, and overlapping explanations are not repeated below.

The semiconductor device according to the tenth embodiment, which is implemented by the SOI substrate, can also achieve substantially the same effects as the semiconductor device according to the first embodiment. The configuration of the SOI substrate in the semiconductor device according to the tenth embodiment can also be applied to the respective semiconductor devices according to the second to eighth embodiments.

### OTHER EMBODIMENTS

As described above, the present disclosure has been described according to the first to tenth embodiments, but it should not be understood that the description and drawings implementing a portion of this disclosure limit the invention. Various alternative embodiments, examples, and operational techniques will be apparent to those skilled in the art from this disclosure.

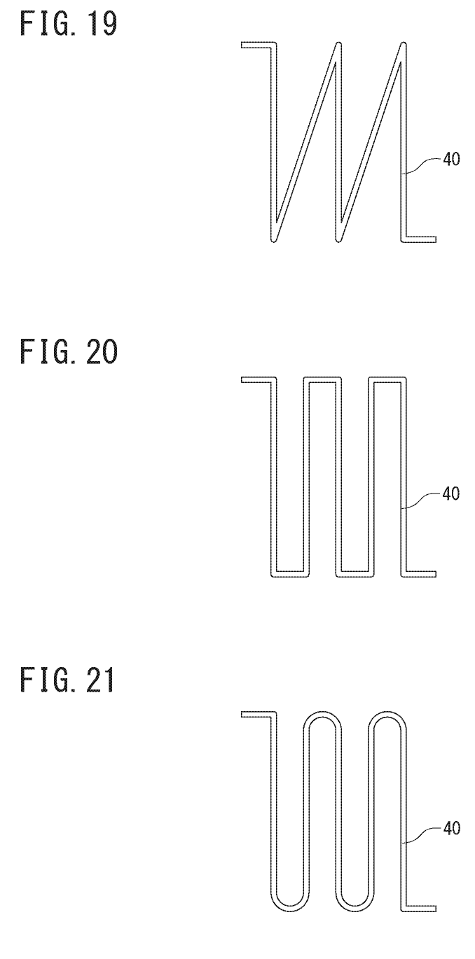

While the respective semiconductor devices according to the first to tenth embodiments have been illustrated above with the case in which the RFPs 40, 60, 81, and 82 have the meandering planar pattern, the meandering shape is not limited to the case as illustrated, and the respective RFPs may have any shape that can be considered as a substantially meandering state. For example, the RFP 40 may have any of meandering planar patterns as illustrated in FIG. 19 to FIG. 21. The respective RFPs 60, 81, and 82 may also have a meandering planar pattern similar to the RFP 40 as illustrated in FIG. 19 to FIG. 21.

In addition, the respective semiconductor devices according to the first to tenth embodiments have been illustrated above with the case in which one end of the respective RFPs 10, 11, 12, 40, 60, 81, 82, (10, 50), (10, 51), (10, 50, 51), and (10, 50, 52, 53) is connected to the VB potential or the VS potential, but are not limited to this case, and the respective one ends only need to be connected to a potential used in the high-side circuit 102. For example, one end of the respective RFPs 10, 11, 12, 40, 60, 81, 82, (10, 50), (10, 51), (10, 50, 51), and (10, 50, 52, 53) may be connected to the drain potential of the level shifter 20a. The drain potential of the level shifter 20a is a potential between the VB potential and the VS potential. Further, when a field plate is implemented by three or more independent RFPs, the respective independent RFPs may be connected to semiconductor regions and potentials different from each other. For example, one end of each of the three RFPs may be connected to the VB potential, the VS potential, and the Dr potential. Further, the number of the independent RFPs implementing the field plate is only required to be at least two, and may be changed as appropriate.

While the semiconductor device according to the first embodiment has been illustrated above with the case of including the high-side circuit 102 for one phase in a single chip, the semiconductor device is not limited to such a case, and may include high-side circuits for plural (three, for example) phases in a single chip. This configuration can also be applied to the respective semiconductor devices according to the second to tenth embodiments.

Further, the respective semiconductor devices according to the first to tenth embodiments have been illustrated above with the HVIC, but the present disclosure may also be applied to any other semiconductor devices other than the HVIC.

In addition, the respective configurations disclosed in the first to tenth embodiments can be combined together as appropriate without contradiction with each other. As described above, the invention includes various embodiments and the like not described herein. Therefore, the scope of the present disclosure is defined only by subject matters recited in claims.

What is claimed is:

1. A semiconductor device comprising:
a base body of a first conductivity-type;
a first well region of a second conductivity-type provided on a top surface side of the base body and provided with a high-side circuit;
a voltage blocking structure provided to surround a circumference of the first well region;
a level shifter provided in the voltage blocking structure; and
first and second resistive field plates provided over the voltage blocking structure with an insulating film interposed, each having one end electrically connected to different semiconductor regions electrically connected to the high-side circuit.

2. The semiconductor device of claim 1, wherein the one end of the first resistive field plate is electrically connected to the first well region.

3. The semiconductor device of claim 1, further comprising a second well region of the first conductivity-type provided on a top surface side of the first well region,
wherein the one end of the second resistive field plate is electrically connected to the second well region.

4. The semiconductor device of claim 1, wherein:
the level shifter includes a carrier reception region; and
the first resistive field plate is located closer to the carrier reception region than the second resistive field plate.

5. The semiconductor device of claim 4, wherein the first resistive field plate has a spiral or meandering planar pattern surrounding the circumference of the first well region.

6. The semiconductor device of claim 4, wherein the first resistive field plate is provided to overlap with the level shifter and has a meandering planar pattern passing across the voltage blocking structure.

7. The semiconductor device of claim 4, wherein:
the first resistive field plate includes a first resistance part located toward the one end of the first resistive field plate, and a second resistance part having a higher resistance than the first resistance part and located toward another end of the first field plate; and
the first resistance part is located closer to the carrier reception region than the second resistance part.

8. The semiconductor device of claim 1, wherein the second resistive field plate implements a voltage-division resistor to detect a potential of the high-side circuit.

9. The semiconductor device of claim 8, wherein the second resistive field plate has a meandering planar pattern passing across the voltage blocking structure.

10. The semiconductor device of claim 9, wherein:
the first resistive field plate has a spiral planar pattern surrounding the circumference of the first well region;
the first resistance part includes a resistance part located at a same level as the second resistive field plate, and a connection part located at an upper level than the resistance part; and
the second resistive field plate is provided under the connection part.

11. The semiconductor device of claim 9, wherein:
the first resistive field plate has a meandering planar pattern surrounding the circumference of the first well region; and
the second resistive field plate is located between turnover parts of the first resistive field plate.

12. The semiconductor device of claim 1, wherein the voltage blocking structure is provided with a slit region of the first conductivity-type surrounding to a circumference of the level shifter.

13. The semiconductor device of claim 12, wherein the first resistive field plate is provided over a region surrounded by the slit region.

14. The semiconductor device of claim 12, wherein a part of the second resistive field plate is provided over the slit region.

15. The semiconductor device of claim 14, wherein the second resistive field plate has a spiral or meandering planar pattern surrounding the circumference of the first well region.

16. The semiconductor device of claim 14, wherein the second resistive field plate is provided to pass through an upper side of the slit region and has a meandering planar pattern passing across the voltage blocking structure.

17. The semiconductor device of claim 1, further comprising a third resistive field plate provided over the voltage blocking structure with an insulating film interposed, and having one end electrically connected to a semiconductor region electrically connected to the high-side circuit.

18. The semiconductor device of claim 1, wherein the one end of each of the first and second resistive field plates is located on a high-potential side, and another end of each of the first and second resistive field plates is located on a low-potential side.

19. The semiconductor device of claim 1, wherein a potential connected to the one end of the first resistive field plate is higher than a potential connected to the one end of the second resistive field plate.

20. The semiconductor device of claim 1, wherein the voltage blocking structure has a voltage blocking region of the second conductivity-type provided to surround the circumference of the first well region so as to be in contact with each other.
